(19) United States
(12) Patent Application Publication
(10) Pub. No.: US 2008/0291744 A1
(43) Pub. Date: Nov. 27, 2008

(54) PORTABLE MEDICAL STORAGE DEVICE AND PROGRAM

(76) Inventor: Alexandria Leinani Hasvold, San Diego, CA (US)

Correspondence Address: PROCOPIO, CORY, HARGREAVES & SAVITCH LLP, 530 B STREET, SUITE 2100, SAN DIEGO, CA, 92101, US

(21) Appl. No.: 12/125,353

(22) Filed: May 22, 2008

Related U.S. Application Data
(60) Provisional application No. 60/939,581, filed on May 22, 2007.

(51) Int. Cl. G11C 13/00; G06Q 50/00

(52) U.S. Cl. 365/185.33; 705/3

(57) ABSTRACT

A medical self-portable device and program on portable drive containing medical information that would be useful and pertinent for doctors and pharmacists to access and have the ability to update. This medical information is necessary for medical personnel to accurately and efficiently treat life-threatening emergency, non-life-threatening emergency, critical care, and/or routine care in doctors' offices or hospitals.

### CROSS-REFERENCE TO RELATED APPLICATIONS

This application claims the benefit of U.S. Provisional Patent Applications Ser. No. 60/939,581, filed May 22, 2007, entitled “Portable Medical Storage Device and Program” which is hereby incorporated by reference in its entirety.

### FIELD OF THE INVENTION

The present invention relates generally to a portable program on a flash hard drive which contains dynamic medical information.

### BACKGROUND OF THE INVENTION

Medical records are normally stored at individual doctors' offices or hospitals in either hard copy or electronic files. Most patients see more than one doctor or are admitted to more than one hospital in their life. Currently, there is no communication between individual doctors' offices or hospitals enabling a patient's medical records to be compiled into one comprehensive group either in hard copy or electronic format. There is further no ability for a new doctor treating a patient to see a complete set of the new patient medical records. There is a great need for all of a patient's historical medical records from each doctor to be compiled and stored in one central location. A complete set of each patient's medical records would enable doctors and hospitals to provide better and more complete care to individuals and would reduce the amount of misdiagnosis or inaccurate prescriptions.

### SUMMARY AND DESCRIPTION OF THE INVENTION

To solve these problems and others, the present invention involves a medical storage device and program which allows all of a patient's medical records to be stored in one location in electronic format. A further benefit of this device is that it is portable and may be carried by the individual patient or other person. This device allows for the records to be updated each time the patient visits the doctor or any other medical facility. This device contains medical information which can be easily and continuously updated. In one embodiment this device can store medical information for multiple patients. In this embodiment the device can be used by doctors to store all of their patients' medical information. In another embodiment the information could be stored on a credit card shaped device which could be read at the doctor's office or hospital. This credit card embodiment has a flip-out connector which can be then plugged into a computer for downloading or uploading data.

The device further allows a patient to provide the device and program to a doctor or hospital enabling this facility to download the information into their system. The information which would be stored in the medical program would include all the medication that the individual is taking at the current time, the dosage, time when taken and how the medication is taken, orally, sublingually, etc. The individual's allergies would be listed along with any ongoing treatments that would be vital to the individual's wellbeing. In one embodiment this invention could also store information consisting of a list of diagnoses that would be matched with certain symptoms and would present possible diagnoses such as diabetes, HTM, or Parkinson's. Further information that could be stored on the device would be the name of the person's attending physician, including address, telephone number and other contact information, along with all the addresses for any physicians who had treated the patient. The information would be pertinent to the attending physician for the care to be provided to the patient in either an emergency or normal situation.

In various embodiments the device would be manufactured as bracelet charms, hair decorations, a brooch, key chains, wrist bands, and possible cell phones. These various embodiments would provide an ideal and convenient way for an individual with specific medical needs and medications to access their medical records. It would also enable medical personnel to access this information and make the best decisions possible in an emergency for the continuance of care and life.

The program contained on the device would be able to be updated at any pharmacy or doctor's office by merely plugging it into the computer where these records are stored. In this manner the device would always have current information available in any pressing emergency. The information would be updated onto the device by connecting it to any computer's USB port. The files could then be viewed, edited and updated. Through existing USB port of any computer the information on the medical device could be accessed and the information could be updated or altered to include new information such as additional medications or changes in existing diagnoses of current medications. The information on this device would enable physicians, dentists and pharmacists to evaluate the medications and decide whether or not there could be negative interactions with other medications on the list. With this ability to evaluate medications a doctor, dentist or pharmacist could prevent error of overmedicating and determining the quality of care by the medications the individual is taking.

This device and program would further enable an emergency department to have immediate access to all the medical history of the individual who is brought in to be treated whether they are local or anywhere in the United States or from overseas. The emergency room or the hospital would be able to take this portable device and connect it to the USB port of their existing computers to download the information. This information would enable the doctors to quickly and efficiently summarize the medical problems and treat it correctly and expeditiously. Additionally the attending physician's or department staff could also contact the patient's other medical providers quickly if a consultation would be necessary to apprise medical issues. The medical device and program would be portable and could be easily carried by the person. In another embodiment this medical device would be small enough to be placed in a person's pocket or on a chain around their neck.

### BRIEF DESCRIPTION OF THE DRAWINGS

FIG. 1 is a perspective view of an embodiment of the medical storage device;

FIG. 2 is a perspective view of the medical storage device illustrated in FIG. 1 plugged into a computer in order to download or upload data; and

FIG. 3 is an embodiment of the medical storage device which is affixed to a key chain.

### DETAILED DESCRIPTION

After reading this description it will become apparent to one skilled in the art how to implement the invention in various alternative embodiments and alternative applications. However, all the various embodiments of the present invention will not be described herein. It is understood that the embodiments presented here are presented by way of an example only, and not limitation. As such, this detailed description of various alternative embodiments should not be construed to limit the scope or breadth of the present invention as set forth below.

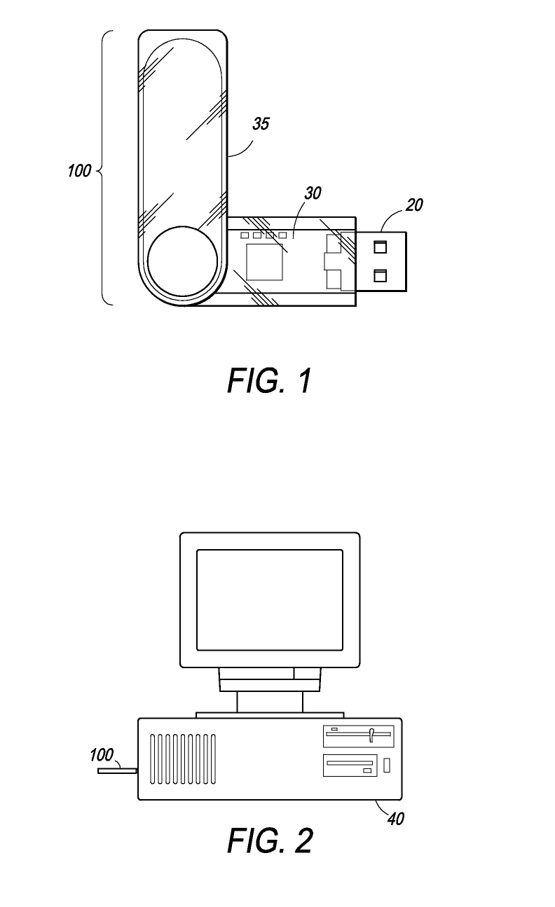

With reference to FIG. 1 a medical storage device (“device”) 100 is shown and displayed. This device 100 is composed of memory data storage plate 30 which stores medical records, wrapped in either a plastic, rubber or other hard coating 35, electronic medical records integrated with a universal serial bus (“USB”) male type connector 20 at one end. The memory data storage plate 30 consists of a small printed circuit board mounted on this board is some simple power circuitry, some random access memory and a small number of surface integrated circuits. In a preferred embodiment the surface integrated circuits include one circuit to interface with the connector 20, one circuit to drive the onboard memory in the device which stores the medical records, and one circuit to control the flash memory. The coating 35 on the exterior of the plate 30 provides protection for the memory data storage plate 30. In a preferred embodiment the device 100 is sized to fit in a persons pocket being no larger than 1 inch wide by 2.5 inches long.

Medical information can be updated onto the device 100 by plugging its USB connector 20 into a computer 40 (FIG. 2). Medical information is then transferred from the computer onto the device 100. In this configuration medical information can also be downloaded from the device onto the computer 40. In one embodiment, information is stored in a set format. This template can be set up to include the patient's contact information (name, address, city, phone, state, cell, zip), name and address of insurance, physicians' names, medical diagnoses, allergies, medication and dosages, other medical information, and emergency contact information. In other embodiments, additional medical information such as actual scanned records or dental information can be stored on the device. This medical information is dynamic in that it can be updated each time the patient goes to the doctor or the hospital. The patient merely needs to carry the device 100 on his/her person and when they goes to the doctor's office hand the device to the doctor so that they can plug it in to their computer and type in or download the updated medical information. This device is also very beneficial to a patient going to a new doctor, in this scenario the doctor is able to input all the patient's historical medical records into their current system and have an accurate picture of the patients health history.

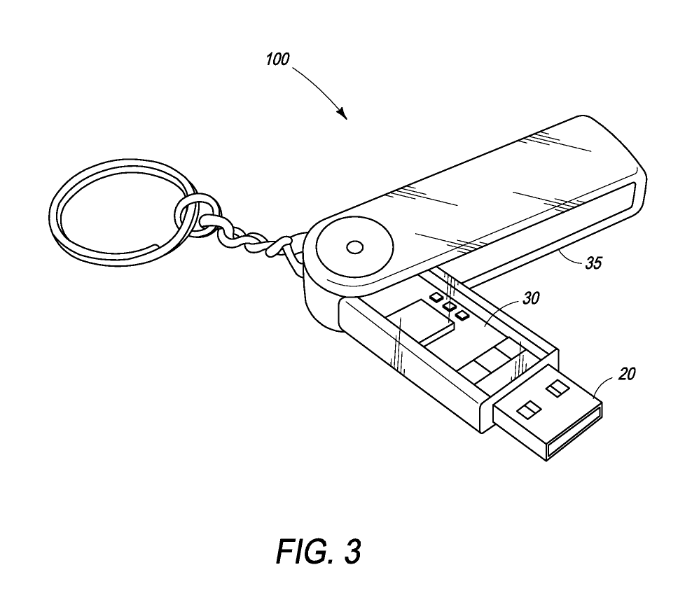

In one embodiment, this device can be made in a key chain type configuration which is displayed in FIG. 3. The device 100 sits in and is protected by its hard coding 35 and can be flipped out by the user to expose the USB connector 20 so that it can be plugged into a USB port of any accepting computer.

In another embodiment, this device can be made in a credit card shape. In a credit card shape, it would slide easily into the user's wallet. The device in this configuration would still have a memory data storage plate 30 consisting of the small printed circuit board with a simple power circuitry, some random access memory, and a small number of service integrated circuits. This embodiment of the device would further have a USB male type connector which could flip out from the credit card so that it extends beyond the edge of the credit card and can be plugged into a computer for the exchange of the medical information.

The above description of disclosed embodiments is provided to enable any person skilled in the art to make or use the invention. Various modifications to the embodiments will be readily apparent to those skilled in the art, the generic principals defined herein can be applied to other embodiments without departing from spirit or scope of the invention. Thus, the invention is not intended to be limited to the embodiments shown herein but is to be accorded the widest scope consistent with the principals and novel features disclosed herein.

1. A medical records storage device which is comprised of:
a memory data storage plate configured to store and allow for updates of medical records;
an exterior coating to protect the memory data storage plate;
electronic medical records; and
a universal serial UBS male connector.

2. The device of claim 1, wherein the memory data storage plate further includes simple power circuitry, random access memory, and a small number of surface integrated circuits.

3. The device of claim 2, wherein the integrated circuits include one to interface with the connector, one to drive the onboard memory which stores the medical records, and one to control the flash memory.

4. The device of claim 1, wherein the medical records include information relating to patient contact, physician names and contact, medical diagnosis, allergies, medication and dosages, and emergency contact.

5. The device of claim 1, which is shaped like a credit card.

6. The device of claim 1, which is configured to be a key chain.

7. A medical record storage device which is comprised of:
a flash drive with a universal serial bus male connector configured to store and transmit medical records to a computer; and
a protective coating covering the flash drive.

8. The device of claim 7, further including a memory data storage plate with simple power circuitry, random access memory and one or more surface integrated circuits.

9. The device of claim 7, wherein medical records include information relating to patient contact, physician names and contact, medical diagnosis, allergies, medication and dosages, and emergency contact.
